(19) United States
(12) Patent Application Publication
(10) Pub. No.: US 2026/0150617 A1
(43) Pub. Date: May 28, 2026

(54) SENSOR ARRAY, SEMICONDUCTOR PROCESSING APPARATUS INCLUDING THE SENSOR ARRAY, AND SEMICONDUCTOR PROCESSING METHOD USING THE SEMICONDUCTOR PROCESSING APPARATUS INCLUDING THE SENSOR ARRAY

(71) Applicants: Samsung Electronics Co., Ltd., Suwon-si (KR); Postech Research and Business Development Foundation, Pohang-si (KR)

(72) Inventors: Hyeyeon YANG, Suwon-si (KR); Sungmin Ahn, Suwon-si (KR); Hyunjin Lee, Suwon-si (KR); Unyong Jeong, Pohang-si (KR)

(73) Assignees: Samsung Electronics Co., Ltd., Suwon-si (KR); Postech Research and Business Development Foundation, Pohang-si (KR)

(21) Appl. No.: 19/388,429

(22) Filed: Nov. 13, 2025

(30) Foreign Application Priority Data
Nov. 22, 2024 (KR) 10-2024-0168862

(51) Int. Cl. H10P 72/00; G01B 7/24; G01L 1/12; H10P 74/20

(52) U.S. Cl. CPC H10P 72/0616; G01B 7/24; G01L 1/127; H10P 74/203

(57) ABSTRACT

Provided is a sensor array including a first coil layer, a second coil layer provided on the first coil layer, a pressure strain layer, and a conductive film layer. The sensor array includes a plurality of unit sensors, each of which includes a first coil provided in the first coil layer, a second coil provided in the second coil layer and corresponding to the first coil, an elastic body provided in the pressure strain layer and deforming according to a change in a pressure applied to a corresponding unit sensor, a conductor provided on the conductive film layer. The plurality of unit sensors may be arranged in a first direction and a second direction, and each of the plurality of unit sensors may be configured to sense a displacement in the first direction, the second direction, and the third direction and a pressure distribution in a third direction.

### CROSS-REFERENCE TO RELATED APPLICATION

This application is based on and claims priority under 35 U.S.C. §119 to Korean Patent Application No. 10-2024-0168862, filed on November 22, 2024, in the Korean Intellectual Property Office, the disclosure of which is incorporated by reference herein in its entirety.

### BACKGROUND

### Field

One or more example of the disclosure relate to a sensor array, a semiconductor processing apparatus having the sensor array, and a semiconductor processing method using a semiconductor processing apparatus having the sensor array.

### Description of the Related Art

Recently, in order to achieve low power consumption and high driving speed, multilayerization of semiconductor processing apparatuses is underway. A manufacturing process of such a semiconductor processing apparatus includes a chip bonding process, which is a process of stacking semiconductor chips called chip on chip (CoC) and chip on wafer (CoW) or mounting semiconductor packages.

As semiconductor chips become thinner and thinner due to the development of three-dimensional semiconductor and chiplet technology, a problem of a warpage in a semiconductor chip has emerged as a major challenge. The warpage refers to a structural variation to a semiconductor chip caused by repeating a process of applying a heat and a pressure to the semiconductor chip in a semiconductor process, and is a factor that degrades performance and reliability of a semiconductor device.

### SUMMARY

In order to solve a warpage problem of a semiconductor chip, a sensor array capable of measuring a pressure within a semiconductor processing apparatus, a semiconductor processing method using the sensor array, and a semiconductor processing apparatus equipped with the sensor array are provided.

Additional aspects will be set forth in part in the description which follows and, in part, will be apparent from the description, or may be learned by practice of the presented embodiments of the disclosure.

According to an aspect of an example embodiment of the disclosure, a sensor array includes: a first coil layer, a second coil layer provided on the first coil layer, a pressure strain layer, and a conductive film layer, wherein the sensor array includes a plurality of unit sensors, and each unit sensor of the plurality of unit sensors includes a first coil provided in the first coil layer, a second coil provided in the second coil layer and corresponding to the first coil, an elastic body providing in the pressure strain layer and deforming according to a change in a pressure applied to a corresponding unit sensor, a conductor provided on the conductive film layer, wherein the plurality of unit sensors may be arranged in a first direction and a second direction, and each unit sensor of the plurality of unit sensors may be configured to sense a displacement in the first direction, the second direction, and a third direction and a pressure distribution in the third direction, the third direction crossing the first direction and the second direction.

The pressure strain layer may be arranged between the conductive film layer and the second coil layer.

The pressure strain layer may be arranged between the first coil layer and the second coil layer.

A protective film layer provided on the conductive film layer may be included.

A constituent material of the first coil may be different from a constituent material of the second coil.

The first coil or the second coil may include any one of gold (Au), copper (Cu), liquid metal, graphene, a carbon nano tube, a metal conductive composite material, and any combination thereof.

A ratio of a resistance of the second coil to a resistance of the first coil may be about 10 to about 10⁴ times.

The conductor may include any one of gold (Au), silver (Ag), copper (Cu), a magnetic metal, a non-magnetic metal, a conductive composite material, a conductive oxide, a conductive polymer, and any combination thereof.

The elastic body may include any one of polymer, a carbon nano tube, graphene, a two-dimensional material, indium tin oxide (ITO), and any combination thereof.

The first coil and the second coil may be configured to receive a voltage and/or a current from a high-frequency oscillation circuit, and the sensor array may be configured to detect a change in an inductance between the first coil and the second coil according to a change in a pressure applied to the sensor array.

The pressure strain layer may include a piezoresistive sensor, or a capacitive pressure sensor.

Shapes of the first coil and the second coil may include any one of a circle, a rectangle, a triangle, a pentagon, and a hexagon.

According to an aspect of an example embodiment of the disclosure, a semiconductor processing apparatus includes: a signal detector including a sensor array configured to detect a change in a pressure applied to the sensor array and an oscillator configured to supply an excitation signal to the sensor array; a signal processor configured to convert a signal obtained from the sensor array into data; and a processor configured to adjust a pressure of the semiconductor processing apparatus based on the data, wherein the sensor array includes: a first coil layer; a second coil layer provided on the first coil layer, a pressure strain layer; and a conductive film layer, wherein the sensor array includes a plurality of unit sensors, and each unit sensor of the plurality of unit sensors includes: a first coil provided in the first coil layer; a second coil provided in the second coil layer and corresponding to the first coil; an elastic body provided in the pressure strain layer and deforming according to a change in a pressure applied to a corresponding unit sensor; a conductor provided on the conductive film layer, and wherein the plurality of unit sensors are arranged in a first direction and a second direction, and each unit sensor of the plurality of unit sensors is configured to sense a displacement in the first direction, the second direction, and a third direction and a pressure distribution in the third direction, the third direction crossing the first direction and the second direction.

The first coil or the second coil may include any one of gold (Au), copper (Cu), liquid metal, graphene, a carbon nano tube, a metal conductive composite material, and any combination thereof.

A ratio of a resistance of the second coil to a resistance of the first coil may be about 10 to about 10⁴ times.

The conductor may include any one of gold (Au), silver (Ag), copper (Cu), a magnetic metal, a non-magnetic metal, a conductive composite material, a conductive oxide, a conductive polymer, and any combination thereof.

The elastic body may include any one of polymer, a carbon nano tube, graphene, a two-dimensional material, indium tin oxide (ITO), and any combination thereof.

The semiconductor processing apparatus may be any one of a die-to-wafer (D2W) bonding device, a chemical mechanical polishing (CMP) device, a cleaning device, or a wafer transfer robot.

According to an aspect of an example embodiment of the disclosure, a semiconductor processing method using a semiconductor processing apparatus includes: measuring, using a sensor array included in the semiconductor processing apparatus, a pressure at which the semiconductor processing apparatus bonds a semiconductor chip onto a substrate; measuring a degree of a warpage of the semiconductor chip according to a change in a pressure applied by the semiconductor processing apparatus; measuring at least one of a surface warpage state or a warpage angle of the semiconductor chip at a predetermined pressure; adjusting a final pressure and a working angle of the semiconductor processing apparatus based on the at least one of the surface warpage state or the warpage angle of the semiconductor chip; and performing a process within the semiconductor processing apparatus based on the final pressure and the working angle, wherein the sensor array includes a plurality of unit sensors, the plurality of unit sensors are arranged in a first direction and a second direction, and each unit sensor of the plurality of unit sensors is configured to sense a displacement in the first direction, the second direction, and a third direction and a pressure distribution in the third direction, the third direction crossing the first direction and the second direction.

The semiconductor processing apparatus may be any one of a die-to-wafer (D2W) bonding device, a chemical mechanical polishing (CMP) device, a cleaning device, or a wafer transfer robot.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram illustrating components of a sensor array according to an example embodiment;

FIGS. 2A and 2B are plan views schematically illustrating a plurality of unit sensors according to example embodiments;

FIG. 3 is an enlarged plan view of one of the unit sensors shown in FIG. 2A;

FIG. 4 is a schematic diagram illustrating components of a sensor array according to another example embodiment;

FIG. 5 is a schematic diagram illustrating components of a sensor array according to another example embodiment;

FIGS. 6A to 6D are plan views illustrating a shape of a unit sensor according to various example embodiments;

FIG. 7 is a block diagram schematically illustrating components of a sensor module including a sensor array according to an example embodiment;

FIG. 8 is a block diagram schematically illustrating components of a pressure sensor including a sensor array according to an example embodiment;

FIGS. 9 and 10 are diagrams schematically illustrating a semiconductor processing apparatus including a sensor array according to example embodiments; and

FIG. 11 is a flowchart illustrating a semiconductor processing method using a sensor array according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a sensor array, a semiconductor processing apparatus including the sensor array, and a semiconductor processing method using the sensor array will be described in detail with reference to the accompanying drawings. Embodiments described below are merely illustrative, and various modifications are possible from these embodiments. In the following drawings, the same reference numerals refer to the same components, and the size of each component in the drawings may be exaggerated for clarity and convenience of description.

Hereinafter, the term “upper portion” or “on” may also include “to be present on the top, bottom, left or right portion on a non-contact basis” as well as “to be present just on the top, bottom, left or right portion on a directly contact basis”.

The terms “first”, “second”, etc. may be used to describe various components, but are used only for the purpose of distinguishing one component from another component. These terms do not limit the difference in material or structure of components.

Singular expressions include plural expressions unless they are explicitly meant differently in context. In addition, when a part “includes” a component, this means that it may include more other components, rather than excluding other components, unless otherwise stated.

In addition, the terms “unit”, “module” or the like mean a unit that processes at least one function or operation, which may be implemented in hardware or software or implemented in a combination of hardware and software.

The use of the term “the” and similar indicative terms may correspond to both singular and plural.

Steps constituting or included in the method may be performed in an appropriate order unless there is a clear statement that the steps should be performed in the order described. In addition, the use of all illustrative terms (e.g., etc.) is simply intended to detail technical ideas and, unless limited by the claims, the scope of rights is not limited due to the terms.

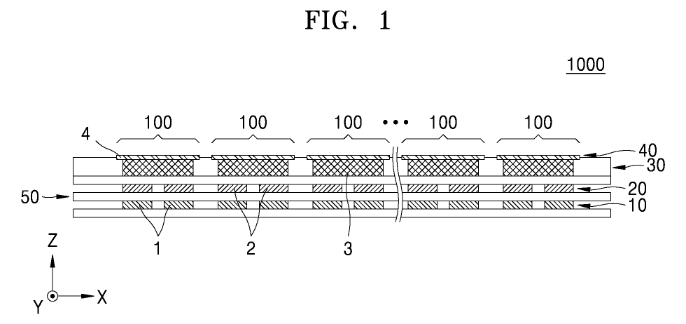

FIG. 1 is a schematic diagram illustrating components of a sensor array according to an example embodiment.

Referring to FIG. 1, a sensor array 1000 may include a first coil layer 10, a second coil layer 20 on the first coil layer 10, a pressure strain layer 30 on the second coil layer 20, and a conductive film layer 40 on the pressure strain layer 30. A spacer layer 50 may be further provided between a plurality of first coil layers 10 and a plurality of second coil layers 20.

The sensor array 1000 may include a plurality of unit sensors 100 arranged in two dimensions in a first direction (e.g., X direction) and a second direction (e.g., Y direction). The plurality of unit sensors 100 may be provided to be spaced apart from each other at predetermined intervals in the first direction (X direction) or the second direction (Y direction). Alternatively, the plurality of unit sensors 100 may be provided to be in contact with each other in the first direction (X direction) and the second direction (Y direction).

Each of the plurality of unit sensors 100 may include a first coil 1 provided in the first coil layer 10, a second coil 2 provided in the second coil layer 20, an elastic body 3 provided in the pressure strain layer 30, and a conductor 4 provided in the conductive film layer 40.

The first coil layer 10 provided in each unit sensor 100 may include the first coil 1. The first coil 1 may include, for example but not limited to, at least one of metal material, a liquid metal, graphene, a carbon nanotube (CNT), a conductive metal composite material, or any combination thereof. The metal material may include at least one of gold (Au), silver (Ag), copper (Cu), or any combination thereof.

The second coil layer 20 provided in each unit sensor 100 may include the second coil 2. The second coil 2 may include at least one of gold (Au), silver (Ag), copper (Cu), a liquid metal, graphene, a CNT, a conductive metal composite material, or any combination thereof. A constituent material of the second coil 2 may be different from a constituent material of the first coil 1. For example, when a resistance of the constituent material of the first coil 1 is R₁, and a resistance of the constituent material of the second coil 2 is R₂, R₂/R₁ representing a ratio of the resistance R₂ of the constituent material of the second coil 2 to the resistance R₁ of the constituent material of the first coil 1 may be about 10 to about 10⁴. In other words, the constituent material of the first coil 1 and the constituent material of the second coil 2 may be selected such that the resistance ratio of the second coil 2 to the first coil 1 is about 10 to about 10⁴.

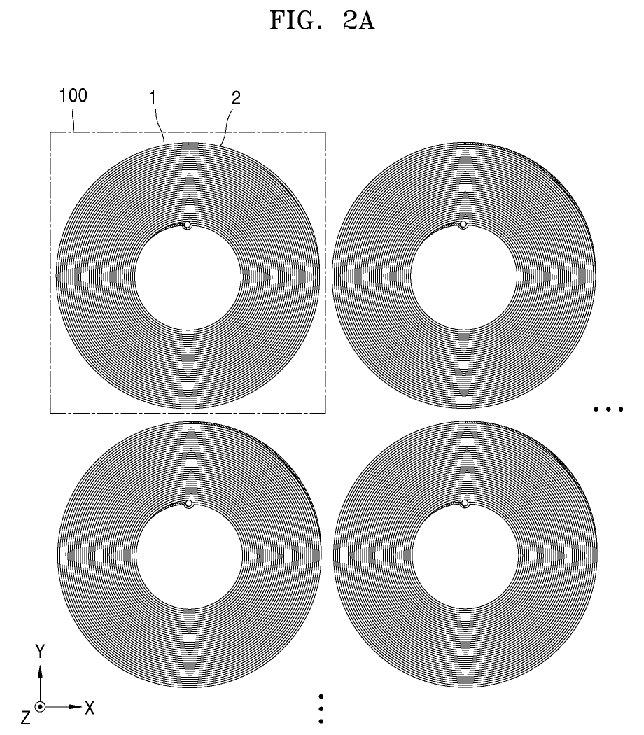

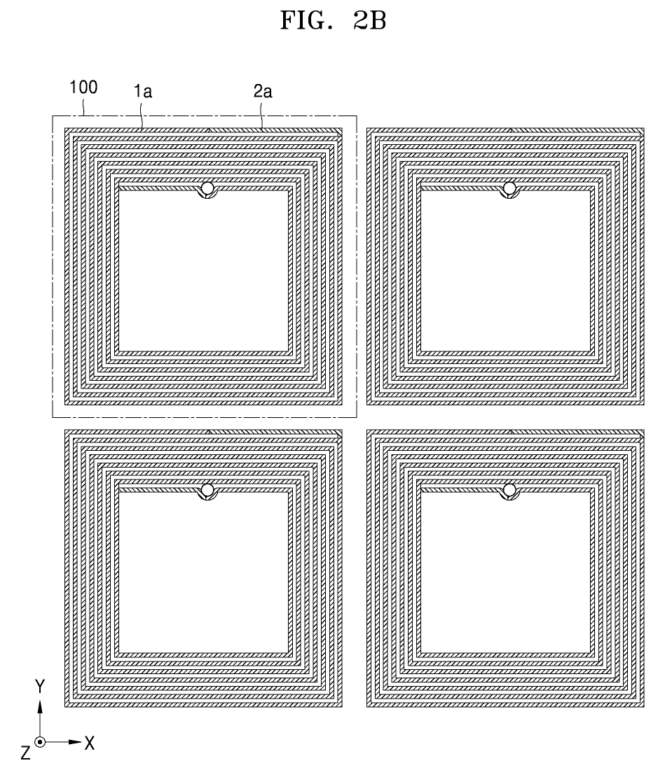

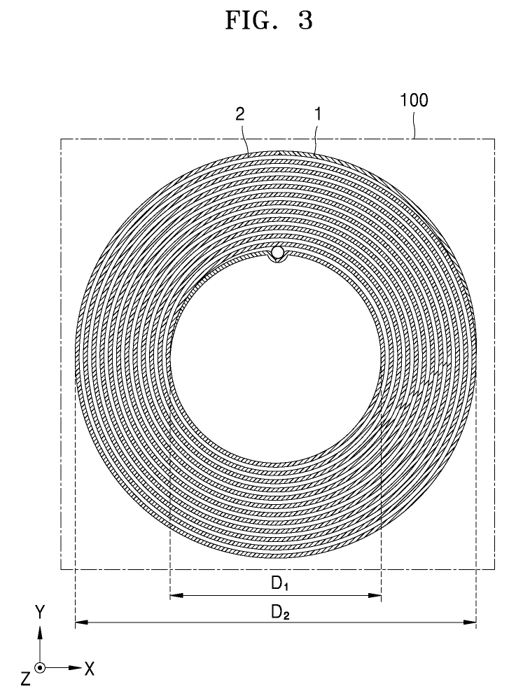

FIGS. 2A and 2B are plan views schematically illustrating a plurality of unit sensors according to embodiments, and FIG. 3 is an enlarged plan view of one of the unit sensors shown in FIG. 2A. Some components are omitted for convenience.

Referring to FIGS. 2A to 2B, the first coil 1, and the second coil 2 provided in a third direction (e.g., Z direction) of the first coil 1 of the unit sensor 100 may have a circular shape as shown in FIG. 2A, or a first coil 1a, and a second coil 2a provided in the third direction (Z direction) of the first coil 1a of the unit sensor 100 may have a rectangular shape, as shown in FIG. 2B. FIGS. 2A and 2B are provided only as examples and the first coil and the second coil may have various shapes. Hereinafter, for convenience, a case in which the first coil 1 and the second coil 2 of the unit sensor 100 have a circular shape is described as an example. The plurality of unit sensors 100 may be two-dimensionally arranged in the first direction (X direction) and the second direction (Y direction). Referring to FIG. 3, each of the unit sensors 100 may include the first coil 1 and the second coil 2 provided in the third direction (Z direction) of the first coil 1. A size of the first coil 1 and A size of the second coil 2 may be approximately the same or similar. That is, an inner diameter of the first coil 1 and an inner diameter of the second coil 2 may be approximately the same or similar, and an outer diameter of the first coil 1 and an outer diameter of the second coil 2 may be approximately the same or similar. For example, each of the first coil 1 and the second coil 2 may have an inner diameter D₁ and an outer diameter D₂.

Referring back to FIG. 1, the pressure strain layer 30 of each unit sensor 100 may include the elastic body 3. The elastic body 3 may include a material capable of elastic strain as a pressure is applied to the elastic body 3. For example, the elastic body 3 may include at least one of a polymer, a nanocomposite material, or any combination thereof. The nanocomposite material may include at least one of CNT, a two-dimensional (2D) material, indium tin oxide (ITO), or any combination thereof. The 2D material may include graphene. The pressure strain layer 30 may have a thickness of about 1 μm to about 10 mm in the third direction (Z direction). The pressure strain layer 30 may include a sensor that detects a change in resistance or capacitance due to strain of the pressure strain layer. For example, the pressure strain layer 30 may include a piezoresistive sensor or a capacitive pressure sensor.

The conductive film layer 40 may include the conductor 4. The conductor 4 may include at least one of a metal material, a magnetic metal material, a non-magnetic metal material, a conductive composite material, a conductive oxide, a conductive polymer, or any combination thereof. The metal material may include at least one of gold (Au), silver (Ag), copper (Cu), or any combination thereof.

In addition, when a current flows through a coil to generate a magnetic field, and when a conductor performs a relative motion with respect to the magnetic field, an eddy current is generated in a direction stopping the relative motion. When a pressure is applied to each unit sensor 100 of the sensor array 1000, the elastic body 3 provided in the pressure strain layer 30 of each unit sensor 100 may be deformed. As the elastic body 3 of each unit sensor 100 is deformed, the conductor 4 provided in the conductive film layer 40 on the pressure strain layer 30 of each unit sensor 100 may move in a direction in which the elastic body 3 is deformed. As the elastic body 3 is deformed, a distance between the conductor 4 and the first coil 1 of each unit sensor 100 changes, and thus, the magnetic field applied to the conductor 4 changes, thereby generating an eddy current for stopping the relative movement of the conductor 4.

A change in an inductance between the first coil 1 and the second coil 2 may occur depending upon a change in an eddy current due to a change in a pressure applied to the unit sensor 100. The sensor array 1000 may detect a change in the inductance depending upon the change in the eddy current between the first coil 1 and the second coil 2 due to the change in the pressure applied thereto.

Accordingly, each unit sensor 100 of the sensor array 1000 may detect a displacement in the first direction (X direction), the second direction (Y direction), and the third direction (Z direction) and a pressure distribution in the third direction (Z direction) in a semiconductor processing apparatus. Each of the unit sensors 100 may be two-dimensionally arranged in the first direction (X direction) and the second direction (Y direction) to be used as a pressure sensor having high spatial resolution and sensitivity. The sensor array 1000 may be used to measure a pressure in a semiconductor processing apparatus, and the sensor array 1000 may be used to adjust a semiconductor process condition by measuring a degree of a warpage of a semiconductor chip generated during a semiconductor process.

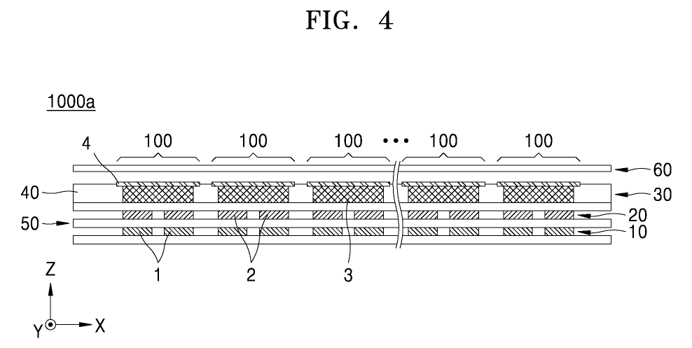

FIG. 4 is a schematic diagram illustrating components of a sensor array according to another embodiment. The difference from FIG. 1 is mainly described, and the same reference numerals denote the same components.

Referring to FIG. 4, a sensor array 1000a may further include a protective film layer 60 on the conductive film layer 40. The protective film layer 60 may include, for example but not limited to, a metal oxide, a polymer material, or a non-conductive film.

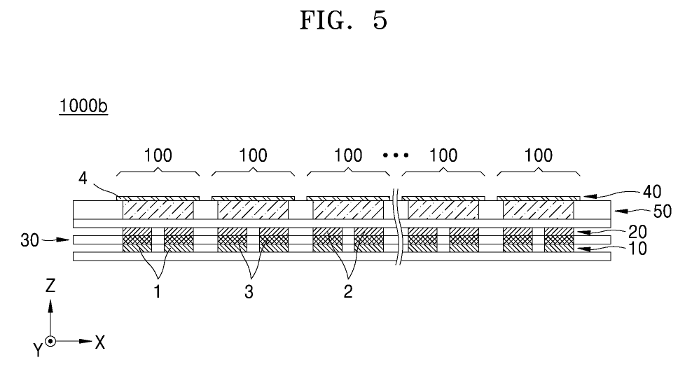

FIG. 5 is a schematic diagram illustrating components of a sensor array according to another embodiment. The difference from FIG. 1 is mainly described, and the same reference numerals denote the same components.

Referring to FIG. 5, a sensor array 1000b may include the first coil layer 10, the pressure strain layer 30 on the first coil layer 10, the second coil layer 20 on the pressure strain layer 30, and the conductive film layer 40 on the second coil layer 20. The spacer layer 50 may be further provided between the second coil layer 20 and the conductive film layer 40.

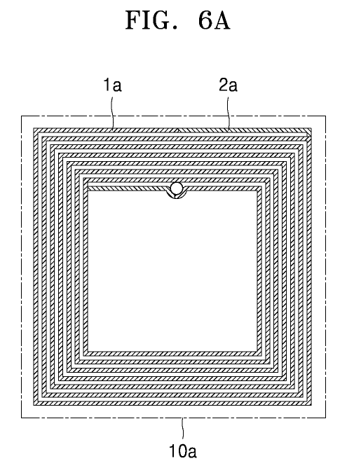

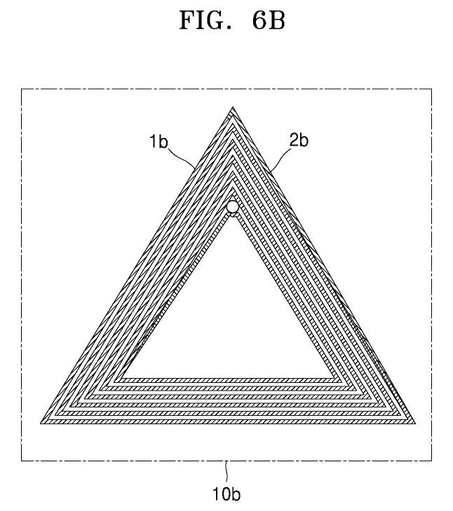

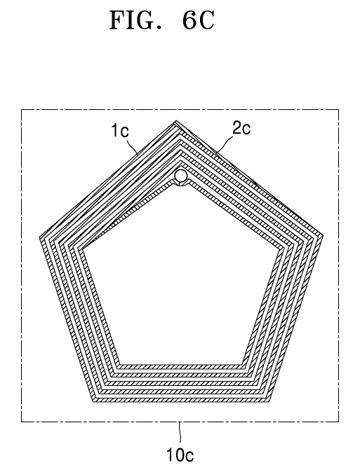

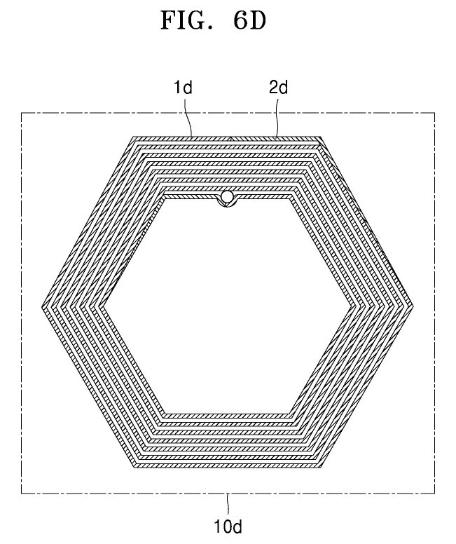

FIGS. 6A to 6D are plan views illustrating a shape of a unit sensor 10a, 10b, 10c, or 10d according to various embodiments. The difference from FIG. 2 is mainly described, and the remaining components are omitted for convenience.

Referring to FIG. 6A, a first coil 1a and a second coil 2a may form a rectangular shape. Referring to FIG. 6B, a first coil 1b and a second coil 2b may form a triangular shape. Referring to FIG. 6C, a first coil 1c and a second coil 2c may form a pentagonal shape. Referring to FIG. 6D, a first coil 1d and a second coil 2d may form a hexagonal shape. As described above, the shapes formed by the first coils 1a, 1b, 1c, and 1d and the second coils 2a, 2b, 2c, and 2d are shown as examples, but they may have various shapes in addition to the shapes described above.

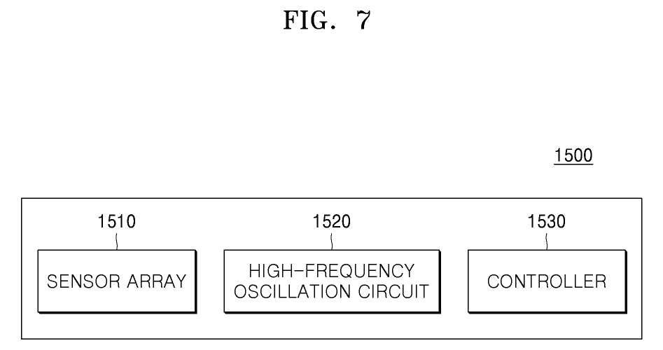

FIG. 7 is a block diagram schematically illustrating components of a sensor module including a sensor array according to an embodiment.

Referring to FIG. 7, a sensor module 1500 may include a sensor array 1510, a high-frequency oscillation circuit 1520, and a controller 1530.

The sensor array 1510 may include one or more of the sensor arrays 1000, 1000a, and 1000b described with reference to FIGS. 1 to 6D. The high-frequency oscillation circuit 1520 may apply a voltage and/or a current to first and second coils of the sensor array 1510. The first coil and the second coil of the sensor array 1510 may receive a voltage and/or a current from the high-frequency oscillation circuit 1520, and the sensor array 1510 may detect a change in an inductance according to a change in a pressure. The sensor array 1510 may transmit a signal generated according to a change in a pressure to the controller 1530. The controller 1530 may amplify or filter a signal output from the sensor array 1510.

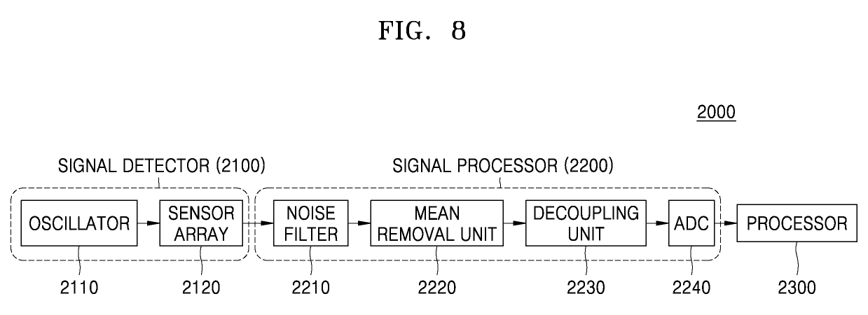

FIG. 8 is a block diagram schematically illustrating components of a pressure sensor including a sensor array according to an embodiment.

Referring to FIG. 8, a pressure sensor 2000 may include a signal detector 2100, a signal processor 2200, and a processor 2300.

The signal detector 2100 may include an oscillator 2110 and a sensor array 2120. The sensor array 1510 may include one or more of the sensor arrays 1000, 1000a, and 1000b described above. The oscillator 2110 may supply an excitation signal to the sensor array 2120. The sensor array 2120 may transmit a signal generated according to a change in a pressure to the signal processor 2200.

The signal processor 2200 may include a noise filter 2210, a mean removal unit 2220, a decoupling unit 2230, and/or an analog-to-digital converter (ADC) 2240. The signal processor 2200 may perform noise removal, mean removal, decoupling, and/or analog-to-digital conversion of the signal obtained from the sensor array 2120.

The processor 2300 may include, for example, a microprocessor. The processor 2300 may adjust the pressure in the semiconductor processing apparatus based on data acquired by the sensor array 2120. The processor 2300 may adjust the pressure in the semiconductor processing apparatus in real time based on a degree of a warpage of the semiconductor chip according to the pressure change in the semiconductor processing apparatus obtained by the sensor array 2120. In this manner (that is, by adjusting the pressure), the processor 2300 may obtain an accurate measurement value by correcting an error of a measurement device based on the data acquired by the sensor array 2120 and/or may increase an accuracy of a process result by correcting a value of a process variable. For example, the processor 2300 may obtain the degree of the warpage of the semiconductor chip according to the change in the pressure, obtain a state and a warpage angle of the semiconductor chip at a predetermined pressure, and adjust a final pressure and a working angle in the semiconductor processing apparatus based on the state and the warpage angle of the semiconductor chip at the predetermined pressure. Thereafter, a semiconductor process may be performed in the semiconductor processing apparatus based on the adjusted final pressure and the working angle.

In FIG. 8, the signal processor 2200 and the processor 2300 are shown as different components, but the processor 2300 may be implemented in a form including the signal processor 2200. In other words, the processor 2300 according to an embodiment may perform the functions of the processor 2300 described above, as well as noise removal, mean removal, decoupling, and/or analog-to-digital conversion of signals obtained from the sensor array 2120.

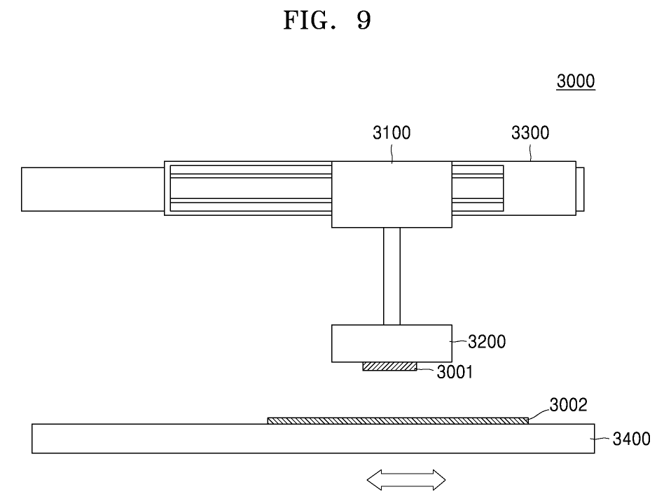

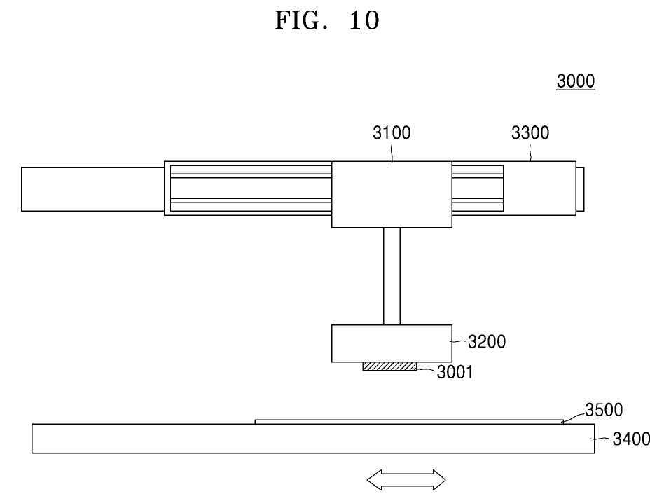

FIGS. 9 and 10 are diagrams schematically illustrating a semiconductor processing apparatus including a sensor array according to embodiments.

Referring to FIGS. 9 to 10, a semiconductor processing apparatus 3000 may include, for example, a die-to-wafer (D2W) bonding device. The D2W bonding device described above may include, for example, a thermal compression (TC) bonder or a hybrid bonder. The semiconductor processing apparatus 3000 may include a bonding head 3100, a bonding tool 3200, a gantry 3300, a bonding stage 3400, and a sensor array 3500. The sensor array 3500 may include one or more of the sensor arrays 1000, 1000a, and 1000b described above.

The bonding head 3100 may bond a semiconductor chip 3001 to a substrate 3002 provided on the bonding stage 3400. When bonding the semiconductor chip 3001 to the substrate 3002, a bonding pressure may be adjusted to prevent a warpage phenomenon of the semiconductor chip 3001. For example, the bonding stage 3400 shown in FIG. 10 may move, and the sensor array 3500 shown in FIG. 10 may be located below the bonding head 3100. The sensor array 3500 may measure a pressure at which the bonding head 3100 of the semiconductor processing apparatus 3000 bonds the semiconductor chip 3001 to the substrate 3002. The bonding pressure of the semiconductor processing apparatus 3000 may be adjusted in real time based on the measured pressure.

In addition, when a pressure is applied to bond the semiconductor chip 3001 to the substrate 3002, a warpage behavior of the semiconductor chip 3001 according to the applied pressure may be determined, and the bonding pressure of the semiconductor processing apparatus 3000 may be adjusted based on the warpage behavior of the semiconductor chip 3001 according to the pressure change. After the bonding pressure of the semiconductor processing apparatus 3000 is adjusted, the sensor array 3500 may move and the bonding stage 3400 may move to be positioned under the bonding head 3100, and then a bonding process may be performed.

Although FIG. 10 shows that the semiconductor processing apparatus 3000 includes a bonding device, pressure control using the sensor array 3500 may also be applied to various semiconductor processing apparatuses such as chemical mechanical polishing (CMP) devices, cleaning devices, or wafer transfer robots.

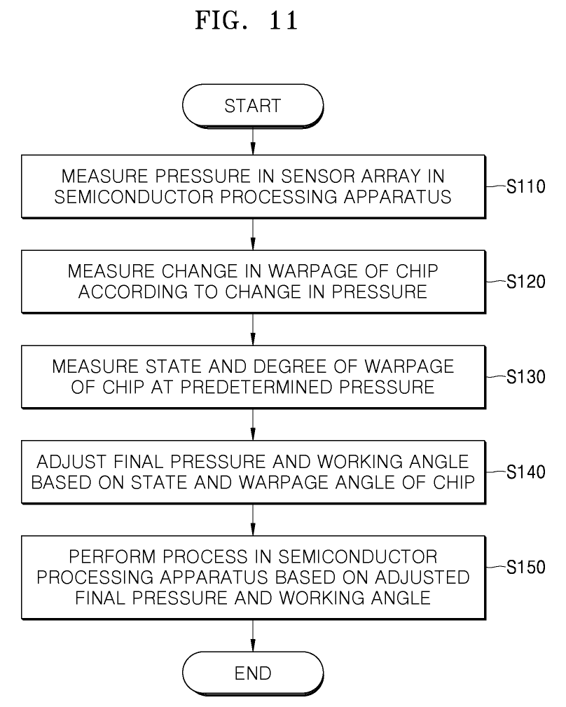

FIG. 11 is a flowchart illustrating a semiconductor processing method using a sensor array according to an embodiment.

Referring to FIG. 11, a pressure at which a semiconductor processing apparatus bonds a semiconductor chip to a substrate may be measured in a sensor array (S110). The sensor array may measure a three-dimensional displacement and a vertical pressure change of the semiconductor chip in the semiconductor processing apparatus. Thereafter, a degree of a warpage of the semiconductor chip according to a change in a pressure applied by the semiconductor processing apparatus may be measured (S120). After measuring the degree of warpage of the semiconductor chip according to the change in the pressure, a state (e.g., surface warpage state) and a tilted angle of the bonding head 3100 (or a warpage angle) of the semiconductor chip at a predetermined pressure may be measured (S130). A final pressure and a working angle in the semiconductor processing apparatus may be adjusted based on the state and the warpage angle of the semiconductor chip at the predetermined pressure (S140). Thereafter, a semiconductor process may be performed in the semiconductor processing apparatus based on the adjusted final pressure and the working angle (S150).

During the semiconductor process, the semiconductor processing apparatus may be configured to measure the pressure of the apparatus by measuring the pressure in the sensor array, analyze the measured data to monitor whether the apparatus is abnormal, measure the warpage behavior of the semiconductor chip according to the pressure change in the semiconductor processing apparatus, and adjust the pressure of the semiconductor processing apparatus based on the warpage behavior of the semiconductor chip according to the pressure change in the semiconductor processing apparatus, thereby improving the accuracy and productivity of the semiconductor process, and improving the quality of the semiconductor device obtained by the semiconductor process.

The sensor array, the semiconductor processing apparatus including the sensor array, and the semiconductor processing method using the sensor array according to various example embodiments have been described with reference to the drawings. According to an embodiment, provided are a sensor array for sensing a pressure at which a semiconductor processing apparatus bonds a semiconductor chip to a substrate, the semiconductor processing apparatus including the sensor array, and a semiconductor processing method.

At least one of the components, elements, modules or units (collectively “components” in this paragraph) represented by a block in the drawings, may be embodied as various numbers of hardware, software and/or firmware structures that execute respective functions described above, according to an example embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

It should be understood that example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A sensor array comprising:
a first coil layer;
a second coil layer provided on the first coil layer;
a pressure strain layer; and
a conductive film layer;
wherein the sensor array includes a plurality of unit sensors, and each unit sensor of the plurality of unit sensors comprises:
a first coil provided in the first coil layer;
a second coil provided in the second coil layer and corresponding to the first coil;
an elastic body provided in the pressure strain layer and deforming according to a change in a pressure applied to a corresponding unit sensor;
a conductor provided on the conductive film layer, and
wherein the plurality of unit sensors are arranged in a first direction and a second direction, and each unit sensor of the plurality of unit sensors is configured to sense a displacement in the first direction, the second direction, and a third direction and a pressure distribution in the third direction, the third direction crossing the first direction and the second direction.

2. The sensor array of claim 1, wherein the pressure strain layer is arranged between the conductive film layer and the second coil layer.

3. The sensor array of claim 1, wherein the pressure strain layer is provided between the first coil layer and the second coil layer.

4. The sensor array of claim 1, further comprising a protective film layer provided on the conductive film layer.

5. The sensor array of claim 1, wherein a constituent material of the first coil is different from a constituent material of the second coil.

6. The sensor array of claim 1, wherein the first coil or the second coil comprises any one of gold (Au), copper (Cu), liquid metal, graphene, a carbon nano tube, a metal conductive composite material, and any combination thereof.

7. The sensor array of claim 1, wherein a ratio of a resistance of the second coil to a resistance of the first coil is about 10 to about 10⁴ times.

8. The sensor array of claim 1, wherein the conductor comprises any one of gold (Au), silver (Ag), copper (Cu), a magnetic metal, a non-magnetic metal, a conductive composite material, a conductive oxide, a conductive polymer, and any combination thereof.

9. The sensor array of claim 1, wherein the elastic body comprises any one of polymer, a carbon nano tube, graphene, a two-dimensional material, indium tin oxide (ITO), and any combination thereof.

10. The sensor array of claim 1, wherein the first coil and the second coil are configured to receive a voltage and/or a current from a high-frequency oscillation circuit, and the sensor array is configured to detect a change in an inductance between the first coil and the second coil according to a change in a pressure applied to the sensor array.

11. The sensor array of claim 1, wherein the pressure strain layer comprises a piezoresistive sensor, or a capacitive pressure sensor.

12. The sensor array of claim 1, wherein shapes of the first coil and the second coil include any one of a circle, a rectangle, a triangle, a pentagon, and a hexagon.

13. A semiconductor processing apparatus comprising:
a signal detector including a sensor array configured to detect a change in a pressure applied to the sensor array and an oscillator configured to supply an excitation signal to the sensor array;
a signal processor configured to convert a signal obtained from the sensor array into data; and
a processor configured to adjust a pressure of the semiconductor processing apparatus based on the data,
wherein the sensor array comprises:
a first coil layer;
a second coil layer provided on the first coil layer,
a pressure strain layer; and
a conductive film layer,
wherein the sensor array comprises a plurality of unit sensors, and each unit sensor of the plurality of unit sensors comprises:
a first coil provided in the first coil layer;
a second coil provided in the second coil layer and corresponding to the first coil;
an elastic body provided in the pressure strain layer and deforming according to a change in a pressure applied to a corresponding unit sensor;
a conductor provided on the conductive film layer, and
wherein the plurality of unit sensors are arranged in a first direction and a second direction, and each unit sensor of the plurality of unit sensors is configured to sense a displacement in the first direction, the second direction, and a third direction and a pressure distribution in the third direction, the third direction crossing the first direction and the second direction.

14. The semiconductor processing apparatus of claim 13, wherein the first coil or the second coil includes any one of gold (Au), copper (Cu), liquid metal, graphene, carbon nano tubes, a metal conductive composite material, and any combination thereof.

15. The semiconductor processing apparatus of claim 13, wherein a ratio of a resistance of the second coil to a resistance of the first coil is about 10 to about 10⁴ times.

16. The semiconductor processing apparatus of claim 13, wherein the conductor includes any one of gold (Au), silver (Ag), copper (Cu), a magnetic metal, a non-magnetic metal, a conductive composite material, a conductive oxide, a conductive polymer, and any combination thereof.

17. The semiconductor processing apparatus of claim 13, wherein the elastic body includes any one of polymer, carbon nano tubes, graphene, a two-dimensional material, indium tin oxide (ITO), and any combination thereof.

18. The semiconductor processing apparatus of claim 13, wherein the semiconductor processing apparatus comprises any one of a die-to-wafer (D2W) bonding device, a chemical mechanical polishing (CMP) device, a cleaning device, or a wafer transfer robot.

19. A semiconductor processing method using a semiconductor processing apparatus, the semiconductor processing method comprising:
measuring, using a sensor array included in the semiconductor processing apparatus, a pressure at which the semiconductor processing apparatus bonds a semiconductor chip onto a substrate;
measuring a degree of a warpage of the semiconductor chip according to a change in a pressure applied by the semiconductor processing apparatus;
measuring at least one of a surface warpage state or a warpage angle of the semiconductor chip at a predetermined pressure;
adjusting a final pressure and a working angle of the semiconductor processing apparatus based on the at least one of the surface warpage state or the warpage angle of the semiconductor chip; and
performing a process within the semiconductor processing apparatus based on the final pressure and the working angle,
wherein the sensor array includes a plurality of unit sensors, the plurality of unit sensors are arranged in a first direction and a second direction, and each unit sensor of the plurality of unit sensors is configured to sense a displacement in the first direction, the second direction, and a third direction and a pressure distribution in the third direction, the third direction crossing the first direction and the second direction.

20. The semiconductor processing method of claim 19, wherein the semiconductor processing apparatus comprises any one of a die-to-wafer (D2W) bonding device, a chemical mechanical polishing (CMP) device, a cleaning device, or a wafer transfer robot.
